(19) United States
(12) Patent Application Publication
(10) Pub. No.: US 2026/0271369 A1
(43) Pub. Date: Sep. 10, 2026

(54) SEMICONDUCTOR DEVICE AND METHOD OF MANUFACTURING THE SAME

(71) Applicants: Kabushiki Kaisha Toshiba, Kanagawa (JP); Toshiba Electronic Devices & Storage Corporation, Kanagawa (JP)

(72) Inventor: Naoki Asano, Nonoichi Ishikawa (JP)

(21) Appl. No.: 19/301,555

(22) Filed: Aug. 15, 2025

(30) Foreign Application Priority Data
Mar. 7, 2025 (JP) 2025-036678

(51) Int. Cl. H10D 64/62; H10D 30/01; H10D 30/66; H10D 64/00; H10D 64/23

(52) U.S. Cl. CPC H10D 64/62; H10D 30/0295; H10D 30/0297; H10D 30/668; H10D 64/117; H10D 64/2527

(57) ABSTRACT

A semiconductor device includes: a first semiconductor region of a first conductivity type that electrically connected to a first electrode; a second semiconductor region of a second conductivity type that sandwiched by insulation regions; a third semiconductor region of a first conductivity type that positioned on the second semiconductor region, and electrically connected to a second electrode; a third electrode arranged side by side with the second semiconductor region; a plurality of interlayer insulation regions that are respectively disposed on the plurality of insulation regions; a first conductive film covering the interlayer insulation region and the third semiconductor region; an intermediate region disposed on the first conductive film in a recessed portion between adjacent ones of the interlayer insulation regions; and a second conductive film that is disposed on the intermediate region and a portion of the first conductive film covering an upper surface of the interlayer insulation region.

### CROSS-REFERENCE TO RELATED APPLICATIONS

This application is based upon and claims the benefit of priority from Japanese Patent Application No. 2025-036678, filed on Mar. 7, 2025, the entire contents of which are incorporated herein by reference.

### FIELD

Embodiments described herein relate generally to a semiconductor device and a method of manufacturing the same.

### BACKGROUND

As one of semiconductor devices, there is known a Metal Oxide Semiconductor Field Effect Transistor (MOSFET) in which a source electrode and a drain electrode are disposed to sandwich a semiconductor layer therebetween, and a gate electrode is disposed in an insulation region (trench region) embedded in the semiconductor layer.

The source electrode includes a barrier metal film that covers the trench region and a trench contact region between trench regions, and a conductive film formed on the barrier metal film. In a case in which a stress and a thickness of the barrier metal film are large, warpage may be caused in the semiconductor layer.

### BRIEF DESCRIPTION OF THE DRAWINGS

FIG. 1 is a cross-sectional view of a semiconductor device according to an embodiment;

FIG. 2A is a process cross-sectional view for explaining a method of manufacturing the semiconductor device according to the embodiment;

FIG. 2B is a process cross-sectional view for explaining the method of manufacturing the semiconductor device according to the embodiment following FIG. 2A;

FIG. 2C is a process cross-sectional view for explaining the method of manufacturing the semiconductor device according to the embodiment following FIG. 2B;

FIG. 2D is a process cross-sectional view for explaining the method of manufacturing the semiconductor device according to the embodiment following FIG. 2C;

FIG. 2E is a process cross-sectional view for explaining the method of manufacturing the semiconductor device according to the embodiment following FIG. 2D;

FIG. 2F is a process cross-sectional view for explaining the method of manufacturing the semiconductor device according to the embodiment following FIG. 2E;

FIG. 2G is a process cross-sectional view for explaining the method of manufacturing the semiconductor device according to the embodiment following FIG. 2F;

FIG. 2H is a process cross-sectional view for explaining the method of manufacturing the semiconductor device according to the embodiment following FIG. 2G;

FIG. 3A is a schematic diagram for explaining influence of dust adhering to a semiconductor layer in a manufacturing process according to a comparative example;

FIG. 3B is a schematic diagram for explaining influence of dust adhering to the semiconductor layer in the manufacturing process according to the comparative example;

FIG. 3C is a schematic diagram for explaining influence of dust adhering to the semiconductor layer in the manufacturing process according to the comparative example;

FIG. 3D is a schematic diagram for explaining influence of dust adhering to the semiconductor layer in the manufacturing process according to the comparative example;

FIG. 3E is a schematic diagram for explaining influence of dust adhering to the semiconductor layer in the manufacturing process according to the comparative example;

FIG. 4A is a schematic diagram for explaining influence of dust adhering to the semiconductor layer in the manufacturing process according to the embodiment;

FIG. 4B is a schematic diagram for explaining influence of dust adhering to the semiconductor layer in the manufacturing process according to the embodiment;

FIG. 4C is a schematic diagram for explaining influence of dust adhering to the semiconductor layer in the manufacturing process according to the embodiment;

FIG. 4D is a schematic diagram for explaining influence of dust adhering to the semiconductor layer in the manufacturing process according to the embodiment;

FIG. 4E is a schematic diagram for explaining influence of dust adhering to the semiconductor layer in the manufacturing process according to the embodiment; and

FIG. 4F is a schematic diagram for explaining influence of dust adhering to the semiconductor layer in the manufacturing process according to the embodiment.

### DETAILED DESCRIPTION

A semiconductor device according to an embodiment includes: a semiconductor layer; a first electrode disposed on a lower side of the semiconductor layer; a second electrode disposed on an upper side of the semiconductor layer; a plurality of insulation regions that are disposed in the semiconductor layer, and disposed at a distance from each other along a second direction orthogonal to a first direction, the first direction being from the first electrode toward the second electrode; a first semiconductor region of a first conductivity type that is disposed in the semiconductor layer and electrically connected to the first electrode; a second semiconductor region of a second conductivity type that is disposed in the semiconductor layer, sandwiched by adjacent ones of the insulation regions, and positioned on the first semiconductor region; a third semiconductor region of a first conductivity type that is disposed in the semiconductor layer, positioned on the second semiconductor region, and electrically connected to the second electrode; a third electrode that is disposed in the insulation region, and arranged side by side with the second semiconductor region along the second direction; a plurality of interlayer insulation regions that are respectively disposed on the plurality of insulation regions, and electrically insulate the second electrode from the third electrode; a first conductive film that constitutes part of the second electrode, and covers the interlayer insulation region and the third semiconductor region; an intermediate region that is disposed on the first conductive film in a recessed portion between adjacent ones of the interlayer insulation regions, and includes a material different from the first conductive film; and a second conductive film that constitutes part of the second electrode, and is disposed on the intermediate region and a portion of the first conductive film covering an upper surface of the interlayer insulation region.

An embodiment according to the present disclosure is described below with reference to the drawings. The embodiment is not intended to limit the present invention. The drawings are merely schematic or conceptual, and ratios or the like of portions are not necessarily the same as real ones. Throughout the specification and the drawings, the same element as an element that has been previously described with reference to a drawing that has been previously described is denoted by the same reference numeral, and detailed description thereof is omitted where appropriate.

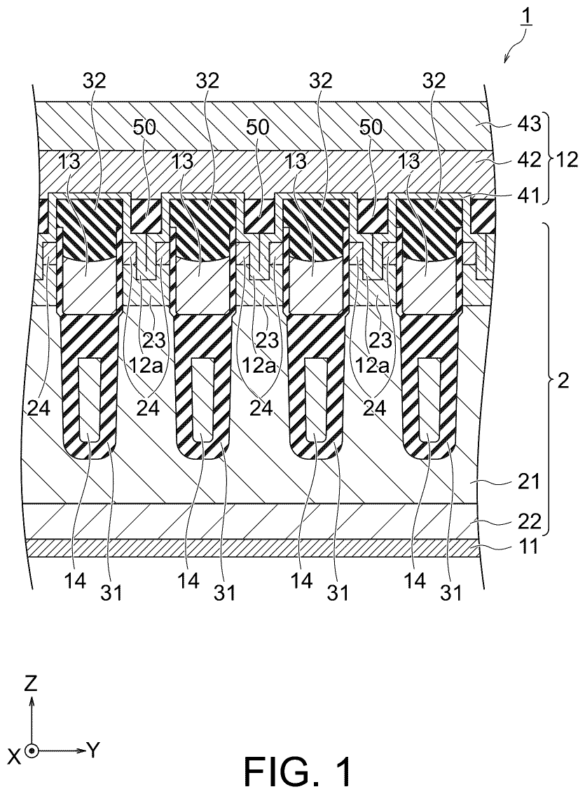

For convenience of explanation, an XYZ orthogonal coordinate system is used as illustrated in FIG. 1 and the like. A Z-axis direction indicates a lamination direction (thickness direction) of the semiconductor device. In the Z-axis direction, a source electrode side is also referred to as “upper”, and a drain electrode side is also referred to as “lower”. However, these expressions are merely for convenience and are not related to the direction of gravity. The Z-axis direction is a first direction in CLAIMS. A Y-axis direction is a second direction in CLAIMS. An X-axis direction is a third direction in CLAIMS.

In the following description, expressions “n⁺”, “n”, “n⁻”, “p⁺”, “p”, and “p⁻” may be used to represent a relative level of impurity concentration in an n-type or p-type semiconductor region. “n⁺” represents n-type impurity concentration relatively higher than “n”, and “n⁻” represents n-type impurity concentration relatively lower than “n”. “p⁺” represents p-type impurity concentration relatively higher than “p”, and “p⁻” represents p-type impurity concentration relatively lower than “p”. In a case in which the semiconductor region includes both of p-type impurities and n-type impurities, these expressions represent a relative level of net impurity concentration after these impurities compensate each other. Each of “n-type”, “n⁺-type”, and “n⁻-type” is an example of a first conductivity type in CLAIMS. Each of “p-type”, “p⁺-type”, and “p⁻-type” is an example of a second conductivity type in CLAIMS. In the following description, “n-type” and “p-type” may be reversed. That is, the first conductivity type may be “p-type”.

The impurity concentration of the semiconductor region can be measured by Secondary Ion Mass Spectrometry (SIMS), for example. The relative impurity concentration level can also be determined based on carrier concentration level obtained by Scanning Capacitance Microscopy (SCM).

Dimensions such as a thickness of a conductive film and a width of a contact can be measured by analysis and the like of a surface and/or a cross section with a Transmission Electron Microscope (TEM), Energy Dispersive X-ray spectroscopy (EDX), or a Scanning Electron Microscope (SEM), for example.

A composition of the conductive film and the like can be analyzed by Energy Dispersive X-ray spectroscopy and the like.

### <Semiconductor Device 1>

A semiconductor device 1 according to the present embodiment will be described with reference to FIG. 1. FIG. 1 is a cross-sectional view of the semiconductor device 1 according to the embodiment. The semiconductor device 1 is configured as a vertical power MOSFET.

The semiconductor device 1 includes a semiconductor layer 2, a drain electrode 11 disposed on a lower side of the semiconductor layer 2, a source electrode 12 disposed on an upper side of the semiconductor layer 2, a plurality of insulation regions 31 disposed in the semiconductor layer 2 along the Y-axis direction, a gate electrode 13 disposed in the insulation region 31, a field plate electrode 14 disposed on the lower side of the gate electrode 13 in the insulation region 31, a plurality of interlayer insulation regions 32 respectively disposed on the plurality of insulation regions 31, and intermediate regions 50 each disposed between the interlayer insulation regions 32 adjacent to each other.

The above-described components of the semiconductor device 1 are described below in detail.

The semiconductor layer 2 is a semiconductor layer sandwiched between the drain electrode 11 and the source electrode 12. The semiconductor layer 2 may be an epitaxial layer, a semiconductor substrate, or a semiconductor substrate and an epitaxial layer formed thereon. In the present embodiment, the semiconductor layer 2 is a silicon (Si) layer. The semiconductor layer 2 contains, for example, arsenic (As), phosphorus (P), or stibium (Sb) as n-type impurities, and contains boron (B) as p-type impurities, for example. The semiconductor layer 2 may be made of a compound semiconductor such as silicon carbide (SiC) or gallium nitride (GaN).

In the semiconductor layer 2, a drift region 21, a drain region 22, a base region 23, and a source region 24 are disposed.

The drift region 21 functions as a drift region of the MOSFET. The drift region 21 is disposed on the drain region 22 (that is, on an upper side of the drain electrode 11). In the present embodiment, the drift region 21 is an n⁻-type semiconductor region. An n-type impurity concentration of the drift region 21 is, for example, equal to or higher than 1×10¹⁵ cm⁻³ and equal to or lower than 2×10¹⁶ cm⁻³.

The drain region 22 functions as a drain region of the MOSFET. The drain region 22 is disposed between the drift region 21 and the drain electrode 11, and electrically connected to the drain electrode 11. In the present embodiment, the drain region 22 is an n⁺-type semiconductor region. An n-type impurity concentration of the drain region 22 is, for example, equal to or higher than 1×10¹⁸ cm⁻³ and equal to or lower than 1×10²¹ cm⁻³.

Each of the drift region 21 and the drain region 22 is an example of a first semiconductor region in CLAIMS. The drain region 22 may also be omitted. In that case, the drift region 21 is directly disposed on the drain electrode 11, and the drain electrode 11 is electrically connected to the drift region 21. Alternatively, the drift region 21 may be omitted. In this case, for example, the drain region 22 is also disposed at a position of the drift region 21.

The base region 23 functions as a base region of the MOSFET. The base region 23 is positioned on the drift region 21, and disposed to be sandwiched between the insulation regions 31 that are adjacent to each other in the Y-axis direction. When a voltage equal to or higher than a threshold is applied to the gate electrode 13, a channel is formed in the base region 23, and a current flows between the drain electrode 11 and the source electrode 12. In the present embodiment, the base region 23 is a p-type semiconductor region. A p-type impurity concentration of the base region 23 is, for example, equal to or higher than 1×10¹⁶ cm⁻³ and equal to or lower than 1×10²⁰ cm⁻³. The base region 23 is an example of a second semiconductor region in CLAIMS.

The source region 24 functions as a source region of the MOSFET. The source region 24 is positioned on the base region 23, and electrically connected to the source electrode 12. An upper surface of the source region 24 constitutes an upper surface of the semiconductor layer 2. The source region 24 is positioned between the base region 23 and the source electrode 12 (conductive film 41) when viewed from the Z-axis direction. In the present embodiment, the source region 24 is an n⁺-type semiconductor region. An n-type impurity concentration of the source region 24 is, for example, equal to or higher than 1×10¹⁸ cm⁻³ and equal to or lower than 1×10²² cm⁻³. The source region 24 is an example of a third semiconductor region in CLAIMS.

In the semiconductor layer 2, the plurality of insulation regions 31 are disposed along the Y-axis direction. That is, the plurality of insulation regions 31 are disposed in the semiconductor layer 2, and disposed at a distance from each other along the Y-axis direction. The insulation region 31 is constituted of an insulator such as silicon oxide or silicon nitride.

A region occupied by the insulation region 31 is also called a trench region. In each trench region, the gate electrode 13 and the field plate electrode 14 extending in the X-axis direction are disposed. A region sandwiched by adjacent trench regions is also called a trench contact region, and the base region 23 and the source region 24 are disposed therein.

The interlayer insulation region 32 is disposed on each of the insulation regions 31. Each of the interlayer insulation regions 32 is disposed so as to project from the semiconductor layer 2 (source region 24). The interlayer insulation region 32 is an interlayer insulation film that electrically insulates the gate electrode 13 from the source electrode 12 or the base region 23. The interlayer insulation region 32 is, for example, constituted of silicon oxide or silicon nitride.

In the present embodiment, the interlayer insulation region 32 is disposed so as to embed the gate electrode 13. This is not limitative; for example, the insulation region 31 may be disposed so as to embed the gate electrode 13, and the interlayer insulation region 32 may be disposed on the insulation region 31.

The drain electrode 11 functions as a drain electrode of the MOSFET. In the present embodiment, the drain electrode 11 is disposed on a lower surface of the semiconductor layer 2, and is in ohmic contact with the drain region 22. The drain electrode 11 contains, for example, at least one of copper (Cu), titanium (Ti), tungsten (W), and aluminum (Al). The drain electrode 11 is an example of a first electrode in CLAIMS.

The source electrode 12 functions as a source electrode of the MOSFET. The source electrode 12 is electrically connected to the source region 24 and the field plate electrode 14. In the present embodiment, the source electrode 12 is connected to the base region 23 via a contact 12a constituted of the conductive film 41. The source electrode 12 is an example of a second electrode in CLAIMS.

The gate electrode 13 functions as a gate electrode of the MOSFET. The gate electrode 13 is disposed in the insulation region 31, and arranged side by side with the base region 23 along the Y-axis direction. The gate electrode 13 is, for example, made of conductive polysilicon and the like containing p-type or n-type impurities. The gate electrode 13 is an example of a third electrode in CLAIMS. As the gate electrode 13, a pair of gate electrodes may be disposed side by side in the Y-axis direction in the insulation region 31.

The field plate electrode 14 is disposed in the insulation region 31, and electrically connected to the source electrode 12. The field plate electrode 14 is electrically insulated from the semiconductor layer 2 by the insulation region 31. By disposing the field plate electrode 14, pressure resistance of the semiconductor device 1 is improved. The field plate electrode 14 is, for example, made of conductive polysilicon and the like containing p-type or n-type impurities. The field plate electrode 14 is not an essential component, and may be omitted.

As illustrated in FIG. 1, in the present embodiment, the source electrode 12 is constituted of the conductive film 41, the conductive film 42, and the conductive film 43.

The conductive film 41 is a barrier metal film, and constitutes part of the source electrode 12. The conductive film 41 covers the interlayer insulation region 32 and the source region 24. More specifically, the conductive film 41 covers an upper surface and a side surface of a portion of the interlayer insulation region 32 that projects from the semiconductor layer 2, and covers an upper surface of the source region 24.

Part of the conductive film 41 passes through the source region 24 along the Z-axis direction to extend up to a middle of the base region 23, and constitutes the contact 12a that electrically connects the source electrode 12 with the base region 23.

A high concentration p-type semiconductor region may be disposed around a bottom (distal end portion) of the contact 12a. This causes minority carriers (positive holes in the present embodiment) accumulated in the base region 23 to be discharged to the source electrode 12 via a high concentration region, reducing a recovery loss. A p-type impurity concentration of the high concentration region is, for example, equal to or higher than 1×10¹⁸ cm⁻³ and equal to or lower than 1×10²² cm⁻³.

In the present embodiment, the conductive film 41 is constituted of tungsten (W). The conductive film 41 may also be constituted of a material other than tungsten, for example, titanium nitride (TiN) or tantalum nitride (TaN). The conductive film 41 may also be constituted of any combination of these materials.

The conductive film 42 is disposed on the intermediate region 50 and a portion of the conductive film 41 covering an upper surface of the interlayer insulation region 32. The conductive film 42 constitutes part of the source electrode 12. In the present embodiment, the conductive film 42 is constituted of an Al—Cu alloy. The conductive film 42 may also be constituted of a material other than the Al—Cu alloy, for example, an Al—Si alloy.

The conductive film 43 is disposed on the conductive film 42, and constitutes part of the source electrode 12. In the present embodiment, the conductive film 43 is an Ni plating film. The conductive film 43 may also be, for example, a plating film of cobalt (Co), platinum (Pt), gold (Au), or palladium (Pd).

The intermediate region 50 is a region formed by filling a recessed portion (groove-like portion in the present embodiment) between the adjacent interlayer insulation regions 32 with a material different from the conductive film 41. The intermediate region 50 is formed on the conductive film 41 constituting an inner wall (a side wall and a low wall) of the recessed portion of the conductive film 41. In the present embodiment, the intermediate region 50 has a lower stress than that of the conductive film 41, and functions as a stress relaxation region. The intermediate region 50 is constituted of silicon oxide (SiOx such as SiO₂). The intermediate region 50 may also be constituted of other insulation materials such as silicon nitride, silicon carbide, a Low-k material, or a High-k material. The intermediate region 50 may also be constituted of a conductive material having a lower stress than that of the conductive film 41 (titanium and the like). As illustrated in FIG. 1, the intermediate region 50 is not disposed on the plurality of interlayer insulation regions 32.

In this manner, in the present embodiment, between the adjacent interlayer insulation regions 32, the intermediate region 50 is embedded between the conductive film 41 and the conductive film 42, so that a void is not present. That is, no void is present in the recessed portion.

### <Working Effect of Semiconductor Device 1>

As described above, in the semiconductor device 1, the intermediate region 50 having a lower stress than that of the conductive film 41 is disposed in the recessed portion between the interlayer insulation regions 32 adjacent to each other. Due to this, the present embodiment can suppress warpage of the semiconductor layer 2. By contrast, in a case in which a film thickness of the conductive film 41 is increased and the recessed portion is filled with the conductive film 41, warpage would be caused in the semiconductor layer 2.

As described above, with the semiconductor device 1 according to the present embodiment, warpage of the semiconductor layer 2 can be suppressed.

### <Method of Manufacturing Semiconductor Device 1>

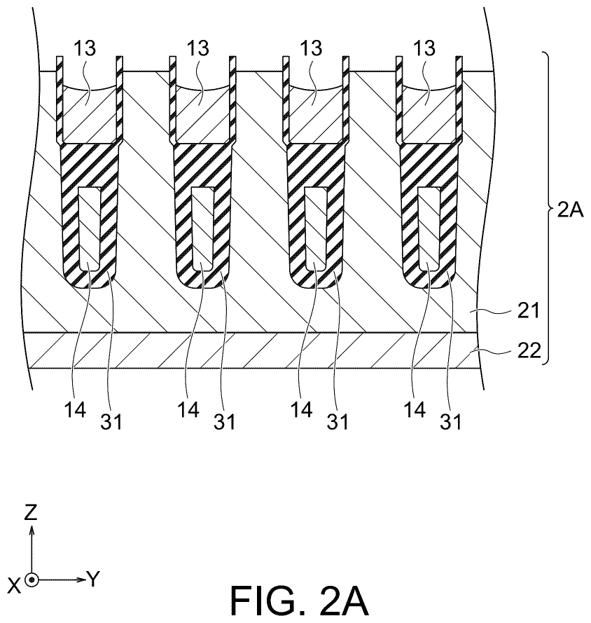

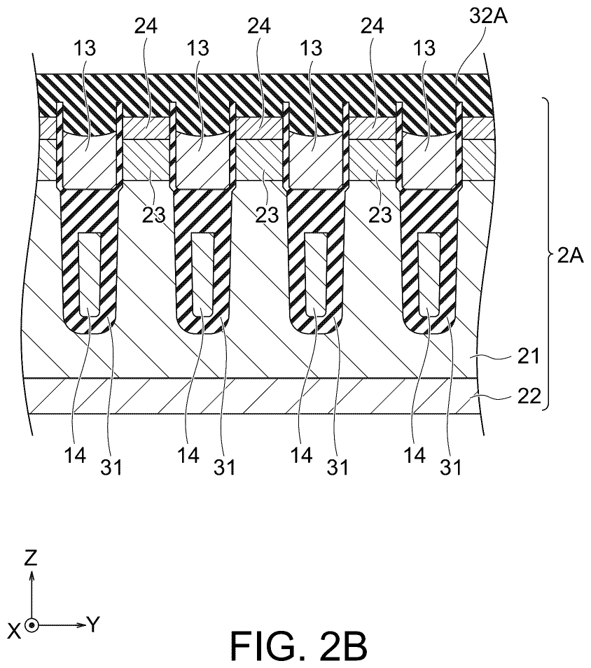

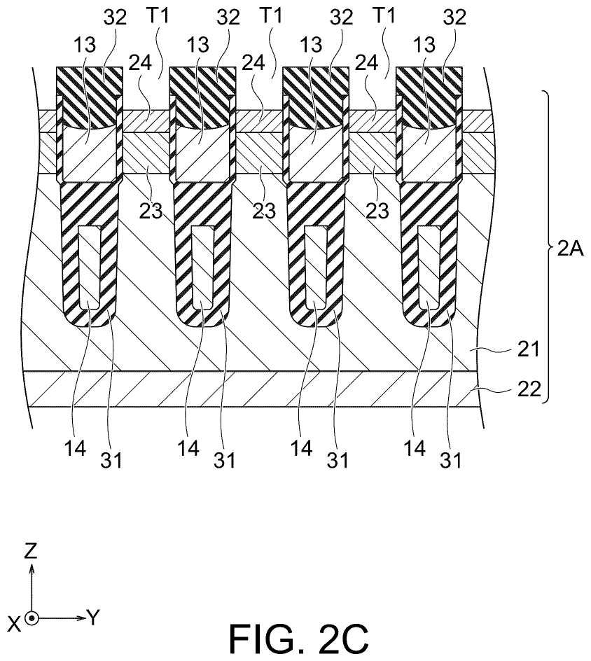

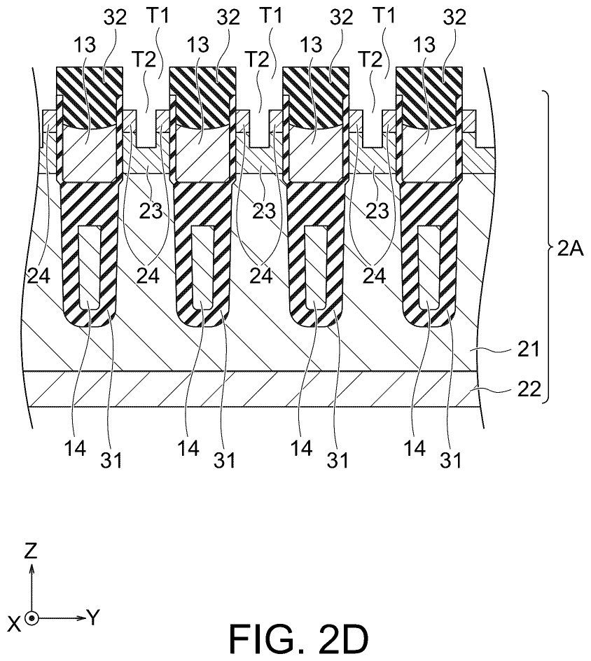

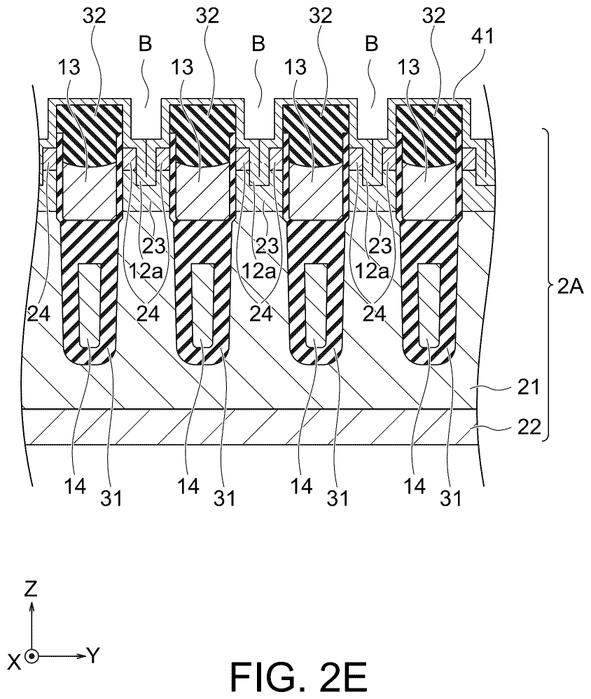

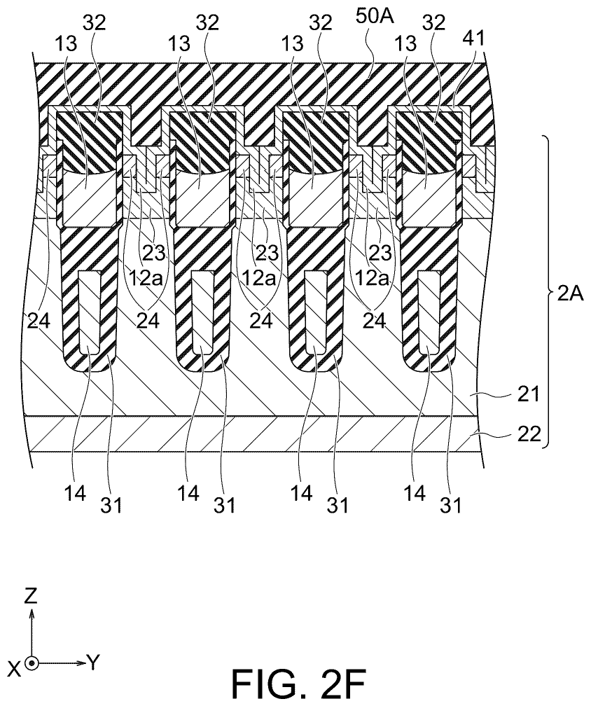

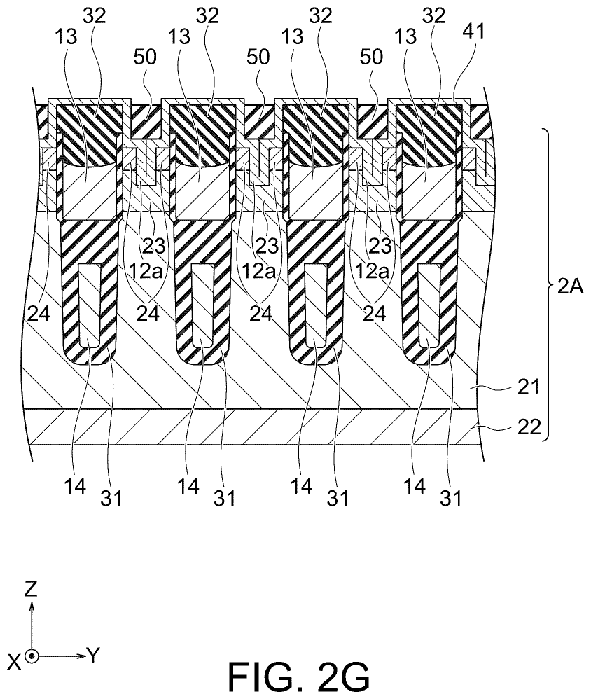

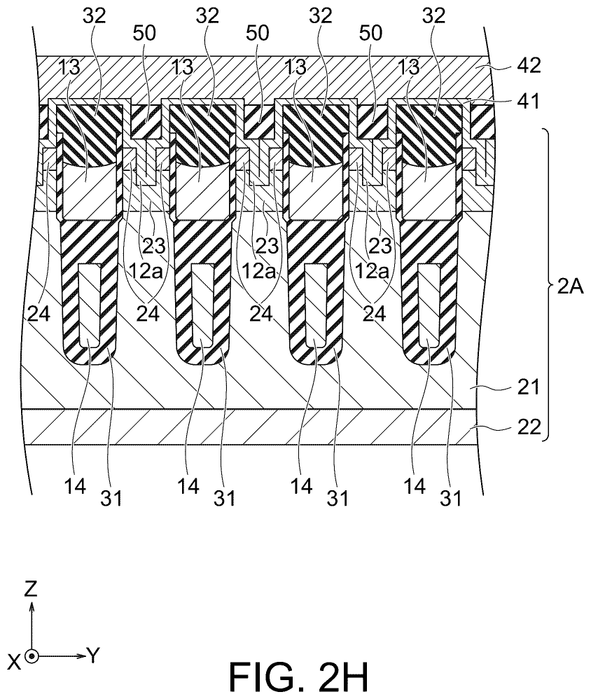

An example of a method of manufacturing the semiconductor device 1 according to the above-described embodiment is described with reference to FIG. 2A to FIG. 2H. FIG. 2A to FIG. 2H are process cross-sectional views for explaining an example of a manufacturing process of the semiconductor device 1.

First, a semiconductor layer 2A illustrated in FIG. 2A is prepared. The drift region 21 and the drain region 22 are disposed in the semiconductor layer 2A over the entire thickness, the plurality of insulation regions 31 are disposed at a distance from each other along a direction (second direction) orthogonal to a thickness direction (first direction) of the semiconductor layer 2A, and the gate electrode 13 and the field plate electrode 14 are disposed in the insulation region 31. The field plate electrode 14 and/or the drain region 22 may also be omitted.

The above-described semiconductor layer 2A can be obtained as follows, for example. First, a semiconductor layer including the drain region 22 constituted of an n⁺-type semiconductor substrate and the drift region 21 constituted of an n⁻-type epitaxial layer disposed on the drain region 22 is prepared. The impurity concentration of the semiconductor substrate may be the same as the impurity concentration of the drift region 21. The semiconductor layer does not necessarily include the drain region 22. In that case, the drain region 22 may be formed by implanting ions into a lower surface of the semiconductor layer before the drain electrode 11 is formed.

An etching mask having a plurality of openings extending in the X-axis direction is formed on the epitaxial layer of the prepared semiconductor layer. Thereafter, etching such as Reactive Ion Etching (RIE) is performed to etch the semiconductor substrate exposed at the openings of the mask, forming a plurality of trenches (gate trenches) extending in the X-axis direction.

Next, by using a thermal oxidation method or Chemical Vapor Deposition (CVD), an insulation region such as a silicone oxide film or a silicon nitride film is formed so as to embed each of the trenches. Subsequently, part of the insulation region (center portion) is removed in a groove shape extending in the X-axis direction by RIE and the like, and a conductive material such as polysilicon is deposited on the groove-like portion after removal by using the CVD method and the like. Thereafter, by etching back an excess conductive material, the field plate electrode 14 is formed. By using a thermal oxidation method, CVD, or the like, the insulation material such as a silicone oxide film or a silicon nitride film is deposited so as to embed the field plate electrode 14, and the insulation region is formed. Subsequently, part of the formed insulation region (center portion) is removed in a wide groove shape extending in the X-axis direction by RIE and the like. Accordingly, the insulation region 31 is formed. Thereafter, by depositing the conductive material such as polysilicon on the groove-like portion after removal by using the CVD method and the like and etching back the excess conductive material, the gate electrode 13 is formed. Through the above-described process, the semiconductor layer 2A illustrated in FIG. 2A is obtained.

Next, as illustrated in FIG. 2B, by using CVD and the like, the insulation material is deposited on an upper surface of the semiconductor layer 2A to form an interlayer insulation layer 32A. The interlayer insulation layer 32A embeds the respective gate electrodes 13. Thereafter, ions of p-type impurities are implanted between the adjacent insulation regions 31 to form the base region 23 as a p-type semiconductor region. Subsequently, ions of n-type impurities are implanted into the base region 23 to form the source region 24 as an n-type semiconductor region.

Next, as illustrated in FIG. 2C, the interlayer insulation layer 32A between the insulation regions 31 is removed to form a trench T1 in which the source region 24 is exposed at a bottom surface. Specifically, an etching mask (not illustrated) having an opening disposed at a region in which the trench T1 is to be formed is formed on the interlayer insulation layer 32A, and the interlayer insulation layer 32A exposed at the opening of the etching mask is removed thereafter by etching processing such as RIE. Through this process, the plurality of interlayer insulation regions 32 are formed on the plurality of insulation regions 31. Each of the interlayer insulation regions 32 embeds the gate electrode 13.

Next, as illustrated in FIG. 2D, part of the source region 24 exposed at the bottom surface of the trench T1 and the base region 23 is removed by RIE and the like to form a trench T2. The trench T2 is narrower than the trench T1, and passes through the source region 24 to extend up to the middle of the base region 23. Specifically, an etching mask (not illustrated) having an opening disposed at a region in which the trench T2 is to be formed is formed on the interlayer insulation region 32 and the source region 24, and the source region 24 exposed at the opening of the etching mask (and part of the base region 23) is removed thereafter by etching processing such as RIE. Alternatively, after the trench T2 is formed, ions of high concentration p-type impurities may be implanted toward a bottom surface of the trench T2 to form a high concentration p-type semiconductor region (not illustrated) around the bottom of the trench T2.

Next, as illustrated in FIG. 2E, a conductive material is deposited on an upper surface of the semiconductor layer by CVD and the like to form the conductive film 41. The conductive film 41 covers upper surfaces of the plurality of interlayer insulation regions 32 and inner walls of trenches T1. The conductive film 41 is also filled into the trench T2 to constitute the contact 12a. The conductive material deposited in this process is, for example, tungsten (W). The conductive material is not limited to tungsten, but may be titanium nitride (TiN), for example. The conductive film 41 functions as a barrier film. A thickness of the conductive film 41 is, for example, 100 nm.

A recessed portion B in FIG. 2E is a recessed space between the adjacent interlayer insulation regions 32. More specifically, the recessed portion B is a space defined by the conductive film 41 covering side surfaces of portions of the adjacent interlayer insulation regions 32 projecting from the source region 24 and the upper surface of the source region 24, and the conductive film 41 constituting the contact 12a.

Next, as illustrated in FIG. 2F, an insulation material is deposited on the upper surface of the semiconductor layer by CVD and the like to form an insulation layer 50A on the conductive film 41. The insulation layer 50A filles the recessed portion B. The insulation material used in this process is, for example, silicon oxide (SiOx such as SiO₂). The insulation layer 50A is a material different from the conductive film 41. For example, the insulation layer 50A has a lower stress than that of the conductive film 41. The insulation material is not limited to silicon oxide, but may be silicon nitride, for example.

Next, as illustrated in FIG. 2G, the insulation layer 50A other than the insulation layer in the recessed portion B is removed by RIE and the like. By doing so, the conductive film 41 covering the upper surface of the interlayer insulation region 32 is exposed, and the intermediate region 50 is formed in the recessed portion B. The upper surface of the intermediate region 50 may be present at substantially the same height as the upper surface of the conductive film 41 covering the upper surface of the interlayer insulation region 32. This can improve flatness of the conductive film 42 to be formed in a subsequent process.

In this etching process, by using an etchant (etching gas, chemicals) having high selectivity between the conductive film 41 and the insulation layer 50A, the process of previously forming the etching mask can be omitted. This can reduce production cost of the semiconductor device 1.

Next, as illustrated in FIG. 2H, a conductive material is deposited on the upper surface of the semiconductor layer by sputtering, CVD, or the like to form the conductive film 42 on the intermediate region 50 and a portion of the conductive film 41 covering the upper surface of the interlayer insulation region 32. The conductive material deposited in this process is, for example, an Al—Cu alloy. The recessed portion B is filled with the intermediate region 50, so that flatness of the upper surface of the conductive film 42 formed in this process is secured. The conductive material used is not limited to the Al—Cu alloy, but may be an Al—Si alloy, for example.

Next, although not illustrated in the drawing, plating processing is performed on the entire surface on the upper side of the semiconductor layer to form the conductive film 43. The conductive film 43 is, for example, an Ni plating film. In a case in which the conductive film 42 is made of a material containing aluminum such as an Al—Cu alloy, zincate treatment is performed on the conductive film 42 before the plating processing is performed. This improves adhesiveness between the conductive film 41 and the conductive film 42. The conductive film 42 is in contact with the conductive film 41 covering the upper surface of the interlayer insulation region 32, so that the conductive film 43 is electrically connected to the contact 12a and the source region 24.

Next, through a process of forming the drain electrode 11 on a lower surface of the semiconductor layer, the semiconductor device 1 illustrated in FIG. 1 is obtained.

According to the method of manufacturing the semiconductor device described above, the intermediate region 50 is formed in the recessed portion B between the interlayer insulation regions 32. Thus, a level difference between upper surfaces of the trench region and the trench contact region is reduced as compared with a case in which the intermediate region 50 is not formed in the recessed portion B and a void is left in the recessed portion B. Accordingly, an upper surface of the conductive film 42 formed on the conductive film 41 and an upper surface of the conductive film 43 formed thereon become flat. This suppresses formation of a portion in which luminance is lowered on a surface of a semiconductor wafer including a plurality of the semiconductor devices 1, as a result which luminance unevenness on a semiconductor wafer surface can be suppressed. Thus, non-defective determination can be properly made in external appearance inspection for the semiconductor wafer.

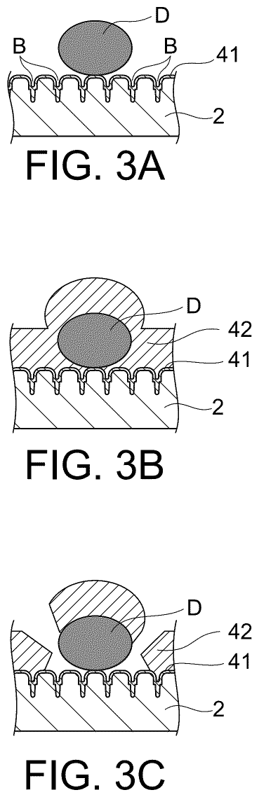

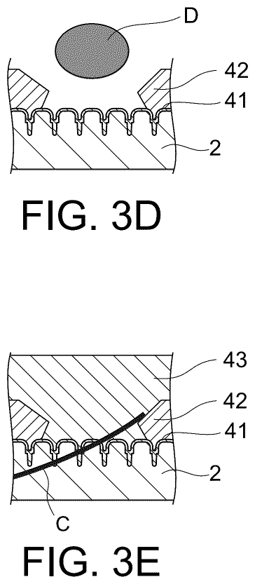

In a case in which the insulation layer 50A is not formed, that is, in a case in which the conductive film 41 is formed and then the conductive film 42 is formed on the conductive film 41, a crack may be caused in the semiconductor layer at the time of performing a heating process (soldering and the like) on the semiconductor device 1. This phenomenon will be described in detail with reference to FIG. 3A to FIG. 3E. For example, as illustrated in FIG. 3A, during formation of the conductive film 41, dust D such as tungsten powder may adhere onto the conductive film 41.

Subsequently, in a process of forming the conductive film 42 made of an Al—Cu alloy film and the like, the conductive film 42 is formed on the dust D and the conductive film 41 and inside the recessed portion B as illustrated in FIG. 3B. Thereafter, at the time of performing zincate treatment on the conductive film 42, a zincate solution penetrates into the conductive film 42 through a portion with a poor covering property of the conductive film 42 due to the dust D, thus accelerating etching of the conductive film 42 around the dust D as illustrated in FIG. 3C. As a result, as illustrated in FIG. 3D, the dust D separates from the conductive film 41, resulting in a condition where the conductive film 42 has disappeared from a portion where the dust D had been present, that is, the conductive film 41 is exposed at the portion where the dust D had been present.

Thereafter, in a process of performing plating processing for forming the conductive film 43, as illustrated in FIG. 3E, the conductive film 43 is brought into direct contact with the conductive film 41 at the portion where the conductive film 42 disappeared, and the recessed portion B is filled with plated metal. Due to this, in the heating process on the semiconductor device 1, a crack C may be caused in the semiconductor layer 2 due to thermal stress.

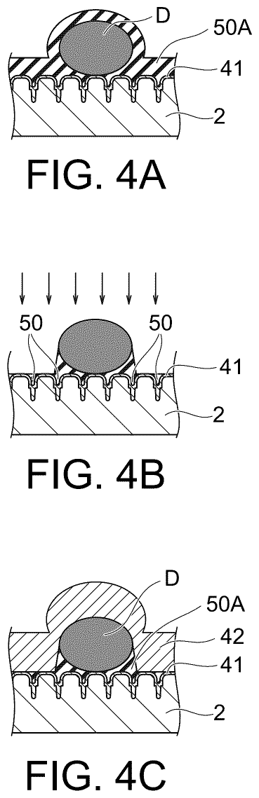

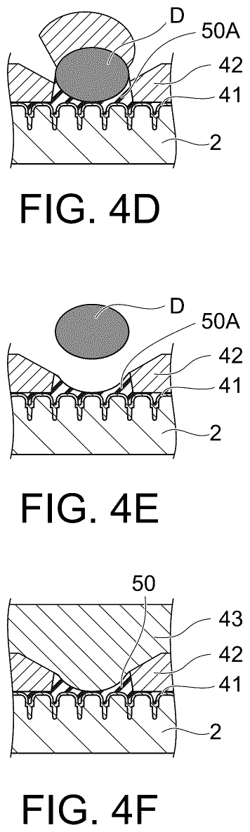

By contrast, according to the method of manufacturing the semiconductor device described above, a crack can be prevented from being caused. This phenomenon will be described in detail with reference to FIG. 4A to FIG. 4F.

As with the above case, it is assumed that the dust D such as tungsten powder adheres onto the conductive film 41 during formation of the conductive film 41. In the manufacturing method according to the present embodiment, as illustrated in FIG. 4A, the insulation material is deposited on the entire surface on the upper side of the semiconductor layer 2 by CVD and the like to form the insulation layer 50A. The insulation layer 50A is formed to envelope the dust D. Thereafter, the insulation layer 50A is etched as illustrated in FIG. 4B, and the conductive film 42 is formed as illustrated in FIG. 4C.

Subsequently, zincate treatment is performed on the conductive film 42. At this point, as illustrated in FIG. 4D, the insulation layer 50A that is left between the dust D and the semiconductor layer 2 blocks the zincate solution. Accordingly, as illustrated in FIG. 4E, the conductive film 41 is covered by the insulation layer 50A and is not exposed after the dust D is separated from the semiconductor layer 2. This prevents the conductive film 43 formed by plating processing from being in direct contact with the conductive film 41 or filling the recessed portion B, as illustrated in FIG. 4F. Thus, according to the manufacturing method in the present embodiment, a crack can be prevented from being caused in the semiconductor layer 2 in the heating process such as soldering. As a result, a manufacturing yield of the semiconductor device can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor layer;
a first electrode disposed on a lower side of the semiconductor layer;
a second electrode disposed on an upper side of the semiconductor layer;
a plurality of insulation regions that are disposed in the semiconductor layer, and disposed at a distance from each other along a second direction orthogonal to a first direction, the first direction being from the first electrode toward the second electrode;
a first semiconductor region of a first conductivity type that is disposed in the semiconductor layer and electrically connected to the first electrode;
a second semiconductor region of a second conductivity type that is disposed in the semiconductor layer, sandwiched by adjacent ones of the insulation regions, and positioned on the first semiconductor region;
a third semiconductor region of a first conductivity type that is disposed in the semiconductor layer, positioned on the second semiconductor region, and electrically connected to the second electrode;
a third electrode that is disposed in the insulation region, and arranged side by side with the second semiconductor region along the second direction;
a plurality of interlayer insulation regions that are respectively disposed on the plurality of insulation regions, and electrically insulate the second electrode from the third electrode;
a first conductive film that constitutes part of the second electrode, and covers the interlayer insulation region and the third semiconductor region;
an intermediate region that is disposed on the first conductive film in a recessed portion between adjacent ones of the interlayer insulation regions, and includes a material different from the first conductive film; and
a second conductive film that constitutes part of the second electrode, and is disposed on the intermediate region and a portion of the first conductive film covering an upper surface of the interlayer insulation region.

2. The semiconductor device according to claim 1, wherein a void is not present in the recessed portion.

3. The semiconductor device according to claim 1, wherein the intermediate region is not disposed on the plurality of interlayer insulation regions.

4. The semiconductor device according to claim 1, wherein the intermediate region is constituted of an insulation material.

5. The semiconductor device according to claim 4, wherein the insulation material is silicon oxide.

6. The semiconductor device according to claim 4, wherein the insulation material is silicon nitride, silicon carbide, a Low-k material, or a High-k material.

7. The semiconductor device according to claim 1, wherein the first conductive film is a tungsten film.

8. The semiconductor device according to claim 1, wherein the first conductive film is titanium nitride or tantalum nitride.

9. The semiconductor device according to claim 1, wherein the second conductive film is an Al—Cu alloy film.

10. The semiconductor device according to claim 1, wherein the second conductive film is an Al—Si alloy film.

11. The semiconductor device according to claim 1, further comprising:
a third conductive film that is disposed on the second conductive film, and constitutes part of the second electrode.

12. The semiconductor device according to claim 11, wherein the third conductive film is a nickel plating film, a cobalt plating film, a platinum plating film, a gold plating film, or a palladium plating film.

13. The semiconductor device according to claim 1, further comprising:
a fourth electrode that is disposed on a lower side of the third electrode inside the insulation region, and electrically connected to the second electrode.

14. The semiconductor device according to claim 1, wherein the first electrode is a drain electrode, the second electrode is a source electrode, the third electrode is a gate electrode, the first semiconductor region includes a drain region, the second semiconductor region includes a base region, and the third semiconductor region includes a source region.

15. The semiconductor device according to claim 1, wherein the first conductivity type is an n-type, and the second conductivity type is a p-type.

16. The semiconductor device according to claim 1, wherein the intermediate region has a lower stress than a stress of the first conductive film.

17. The semiconductor device according to claim 1, wherein part of the first conductive film constitutes a contact configured to electrically connect the second electrode with the second semiconductor region, and the contact passes through the third semiconductor region along the first direction to extend up to a middle of the second semiconductor region.

18. A method of manufacturing a semiconductor device, the method comprising:
preparing a semiconductor layer in which a first semiconductor region of a first conductivity type is disposed over the entire thickness, a plurality of insulation regions are disposed at a distance from each other along a second direction orthogonal to a first direction, the first direction being a thickness direction, and a gate electrode is disposed in the insulation region;
forming an interlayer insulation layer by depositing an insulation material on an upper surface of the semiconductor layer;
implanting ions of impurities of a second conductivity type between adjacent ones of the insulation regions, and forming a second semiconductor region of a second conductivity type on the first semiconductor region sandwiched between adjacent ones of the insulation regions;
implanting ions of impurities of a first conductivity type into the second semiconductor region, and forming a third semiconductor region of a first conductivity type on the second semiconductor region;
forming a plurality of interlayer insulation regions on the plurality of insulation regions by removing the interlayer insulation layer between adjacent ones of the insulation regions, and forming a first trench in which the third semiconductor region is exposed at a bottom surface;
forming a second trench that passes through the third semiconductor region exposed at the bottom surface of the first trench to extend up to a middle of the second semiconductor region, and is narrower than the first trench;
depositing a conductive material on the upper surface of the semiconductor layer to form a first conductive film that covers upper surfaces of the plurality of interlayer insulation regions and an inner wall of the first trench and filles the second trench;
depositing an insulation material on the upper surface of the semiconductor layer to form, on the first conductive film, an insulation layer that includes a material different from the first conductive film and filles a recessed portion between adjacent ones of the interlayer insulation regions;
removing the insulation layer other than the insulation layer in the recessed portion to expose the first conductive film covering an upper surface of the interlayer insulation region, and forming an intermediate region in the recessed portion;
depositing a conductive material on the upper surface of the semiconductor layer to form a second conductive film on the intermediate region and a portion of the first conductive film covering the upper surface of the interlayer insulation region; and
forming a third conductive film on the second conductive film.

19. The method of manufacturing the semiconductor device according to claim 18, wherein
the second conductive film is made of a material containing aluminum, and
zincate treatment is performed on the second conductive film before the third conductive film is formed.

20. The method of manufacturing the semiconductor device according to claim 18, wherein the insulation layer has a lower stress than a stress of the first conductive film.
